(19) United States
(12) Patent Application Publication
(10) Pub. No.: US 2026/0025108 A1
(43) Pub. Date: Jan. 22, 2026

(54) Method for predistorting an input signal in order to compensate for the effect of a non-linear transfer function of a power amplifier, corresponding computer program products and devices

(71) Applicants: UNIVERSITE DE BORDEAUX, BORDEAUX (FR); INSTITUT POLYTECHNIQUE DE BORDEAUX, TALENCE Cedex (FR); CENTRE NATIONAL DE LA RECHERCHE SCIENTIFIQUE, PARIS CEDEX 16 (FR)

(72) Inventors: François RIVET, TALENCE (FR); Yann DEVAL, BORDEAUX (FR); Hervé LAPUYADE, LEOGNAN (FR); Eric KERHERVE, PESSAC (FR); Nathalie DELTIMPLE, PESSAC (FR); Maxandre FELLMANN, TALENCE (FR)

(21) Appl. No.: 18/866,938

(22) PCT Filed: May 16, 2023
(86) PCT No.: PCT/EP2023/063057

§ 371 Date: Nov. 18, 2024

(30) Foreign Application Priority Data
May 19, 2022 (FR) FR2204803

(51) Int. Cl. H03F 1/32; H03F 3/24

(52) U.S. Cl. CPC H03F 1/3258; H03F 1/3247; H03F 3/245; H03F 2200/451

(57) ABSTRACT

A method for predistorting an input signal with a view to compensating for the effect, on a radiofrequency signal generated from the input signal, of a non-linear transfer function of a power amplifier configured to amplify the radiofrequency signal. The method includes: carrying out a Walsh transform of a series of M terms dependent on temporal samples of the input signal delivering sequential components of a corresponding transformed series; calculating a sum of a plurality of operands resulting from the product between, a piece of data dependent on at least one element of a transformed series and a corresponding predistortion coefficient, delivering a corresponding sequential component of a predistorted transformed input signal: and carrying out an inverse Walsh transform of the sequential components of the predistorted transformed input signal, delivering an output signal for the generation of the radiofrequency signal.

### CROSS REFERENCE TO RELATED APPLICATIONS

This application is a National Stage of International Application No. PCT/EP2023/063057, having an International filing date of 16 May 2023, which designated the United States of America, and which International Application was published under PCT Article 21 (2) as WO Publication No. 2023/222655, which claims priority from and the benefit of French Patent Application No. 2204803 filed on 19 May 2022, the disclosures of which are incorporated herein by reference in their entireties.

### BACKGROUND

### Field

The field of the disclosure is that of data transmission through the use of a radiofrequency signal.

More particularly, the disclosure relates to a predistortion method in order to compensate for the effect of a non-linear transfer function of a power amplifier configured to amplify such a radiofrequency signal.

Thus, the disclosure has applications, in particular, yet not exclusively, in the field of mobile telephony (for example 4G or 5G networks as defined by 3GPP (standing for “3rd Generation Partnership Project” in English)), WLAN wireless local area networks (standing for “Wireless Local Area Network” in English, for example using the WiFi), digital broadcasting systems (DVB-T (standing for “Digital Video Broadcasting-Terrestrial” in English), ISDB-T (standing for “Integrated Services Digital Broadcasting-Terrestrial” in English), DAB (standing for “Digital Audio Broadcasting” in English), high-speed wireless Internet access (WiMAX), asymmetric digital links (xDSL), point-to-point links, etc.

### BRIEF DESCRIPTION OF RELATED DEVELOPMENTS

OFDM (standing for “Orthogonal Frequency Division Multiplex” in English) or WCDMA (standing for “Wideband Code Division Multiple Access” in English) communications techniques allow considerably increasing the spectral efficiency of digital communications systems to respond to the exponential growth thereof. However, the waveforms implemented in the context of these techniques have a high peak-to-average power ratio, or PAPR (standing for “Peak-to-Average Power Ratio” in English). The result is that these waveforms are very sensitive to the non-linearities introduced by the power amplifiers, or PA (standing for “Power Amplifier” in English). In particular, such non-linearities distort the amplitude and, where appropriate, the phase of the useful radiofrequency signal. This leads to the creation of interferences in the adjacent communication channels and a degradation of the amplitude of the error vector, or EVM (standing for “Error Vector Magnitude” in English).

To avoid these problems, one possibility consists in exploiting the linear amplification area of the PA. However, the energy efficiency of the amplification in the linear region drops considerably in comparison with the efficiency in the non-linear region when the PA operates close to the saturated power.

Alternatively, the digital predistortion, or DPD (standing for “Digital PreDistortion” in English), consists in compensating for the distortions induced by the non-linear transfer function of the PA in order to correctly transmit the modulated signals while taking advantage of the high energy efficiency of the non-linear region of the transfer function of the PA. According to the DPD approach, as described for example in the article by A. Katz, J. Wood, and D. Chokola, “The evolution of pa linearization: From classic feedforward and feedback through analog and digital predistortion,” IEEE Microwave Magazine, vol. 17, no. 2, pp. 32-40, 2016, a predistortion block (i.E. implementing an inverse model of the transfer function of the PA) is implemented in the digital domain upstream of the PA within a emitter so that the complete system behaves like a linear system.

Moreover, because of the changes in behavior of the PA over time (drift of the parameters of the PA for example according to the temperature, the aging), the parameters of the model implemented in the predistortion block should be updated over time. Thus, [FIG. 1] illustrates a typical DPD architecture. The samples x[n] of the input signal x, herein in baseband, are generated digitally according to the used communication standard (bitrate, encoding, modulation scheme, etc.).

More particularly, the samples x[n] are processed by the predistortion block 110 delivering predistorted samples z[n] which are converted into an analog signal by a DAC 120 (standing for “Digital-to-Analog Converter” in English). The analog signal is transposed into radiofrequencies by a mixer 130 feed by a local oscillator 140. The radiofrequency signal is filtered by a filter 150 to suppress its image. Afterwards, the obtained signal is amplified by the PA 160 before radiation by the antenna. Moreover, in order to track the behavior changes of the PA 160 over time, a coupler 170 is added at the output of the PA 160 to extract a signal representative of the radiofrequency signal as amplified by the PA 160. This representative signal is transposed into low frequencies by a mixer 130 also fed by the local oscillator 140. The signal thus transposed is filtered by an anti-aliasing filter 180 before sampling by an ADC 180 (standing for “Analog-to-Digital Converter” in English). Thus, the ADC 180 delivers the samples y[n] used by the predistortion block 110 in order to update its model. More particularly, the model implemented in the predistortion block 110 is calculated so that the spectral regrowths added onto the predistorted samples z[n] compensate for those related to the non-linearity of the PA 160. In practice, the transfer function of the predistortion block 110 applies a pre-emphasis of the highest levels of the samples x[n] ([FIG. 1a]) so as to compensate for the saturation of the transfer function of the PA 160 ([FIG. 1b]). When the transfer function of the predistortion block 110 corresponds to that of the PA 160, the overall system has a linearized transfer function ([FIG. 1c]).

Moreover, DPD techniques are conventionally classified into three categories according to the considered frequency plan:
Baseband predistortion;
Intermediate frequency predistortion; and
Radiofrequency predistortion.

The most widely adopted technique is the baseband predistortion which operates at the lowest sampling frequency in comparison with the other aforementioned two techniques. Thus, it may be considered to implement a predistortion according to a known baseband method on a DSP (standing for “Digital Signal Processor” in English) or an FPGA (standing for “Field-programmable gate array” in English). However, the cost in terms of digital resources of such known methods makes it difficult to consider an intermediate frequency or radiofrequency implementation. Moreover, searching for the model to implement in the predistortion block 110 involves an iterative algorithm which has a considerable computational complexity.

Thus, there is a need for a predistortion technique having a reduced computational load in comparison with known techniques, enabling for example an implementation in baseband as well as in intermediate frequency and even directly in radiofrequencies.

### SUMMARY

In an aspect of the disclosure, a method is provided for predistorting an input signal to compensate for the effect, on a radiofrequency signal generated from the input signal, of a non-linear transfer function of a power amplifier configured to amplify the radiofrequency signal. According to such a method, an electronic device performs:
carrying out a Walsh transform of at least one series of M terms dependent on at least one series of M temporal samples of the input signal delivering M sequential components of at least one corresponding transformed series;
for at least one given sequential component of the Walsh domain, calculating at least one sum of a plurality of operands resulting from the product between, on the one hand, a piece of data dependent on at least one element, corresponding to the given sequential component, of a transformed series and, on the other hand, a corresponding predistortion coefficient delivering a sequential component of a predistorted transformed input signal. At least one piece of data is dependent on at least one dyadic convolution between two elements, corresponding to the given sequential component, each belonging to a transformed series and/or being dependent on at least one dyadic self-convolution of an element, corresponding to the given sequential component, of a transformed series. The sum follows a structure of a Volterra series, dependent on temporal samples of the input signal, transposed into the Walsh domain. The predistortion coefficients are determined in order to compensate for the effect of the transfer function of the power amplifier.

Said repeated calculation for the M sequential components of the Walsh domain delivering M sequential components of the predistorted transformed input signal
carrying out an inverse Walsh transform of the M sequential components of the predistorted transformed input signal delivering an output signal for the generation of the radiofrequency signal.

Thus, the disclosure provides a novel and inventive solution for compensating for the effect of the non-linear transfer function of the power amplifier.

More particularly, it is herein proposed to implement the predistortion model in the Walsh domain. Indeed, the binary structure of the Walsh sequences and the structure of the digital calculations that result therefrom in the Walsh domain allow reducing the computational load in comparison with known techniques. In particular, such an approach enables an implementation of the predistortion model in baseband as well as in intermediate frequency and even directly in radiofrequencies.

More particularly, such a model is based on the assessment of sums each corresponding to a sequential component of a Volterra series transposed into the Walsh domain.

In some aspects, the Walsh transform is applied to a plurality of series of M terms dependent on at least one series of M temporal samples of the input signal delivering M sequential components of a plurality of corresponding transformed series. Said at least one piece of data depends on:
at least one dyadic convolution between two elements, corresponding to the given sequential component, each belonging to a transformed series of the plurality of transformed series; and/or
at least one dyadic self-convolution of an element, corresponding to the given sequential component, of a transformed series of the plurality of transformed series.

The sum follows a structure of a Volterra series, dependent on the plurality of series of M temporal samples of the input signal, transposed into the Walsh domain.

In some aspects, at least one series of M terms comprises at least one term dependent on:
the product between two temporal samples of the input signal; and/or
at least one temporal sample of the input signal raised to an integer power.

Thus, all or part of the multiplications of the samples of the input signal are implemented in the time domain.

In some aspects, the Walsh transform is applied to a plurality of series of M terms dependent on a series of M temporal samples of the input signal delivering M sequential components of a plurality of corresponding transformed series. Said at least one piece of data depends on at least one dyadic self-convolution of an element, corresponding to the given sequential component, of a transformed series of the plurality of transformed series.

In some aspects, at least one series of M terms comprises at least one term dependent on at least one temporal sample of the input signal raised to an integer power.

In some aspects, the Walsh transform is applied to a series of M terms corresponding to a given series of M temporal samples of the input signal delivering M sequential components of a corresponding transformed series. Said calculation comprises calculating a sum of M operands, the i-th operand, i an integer from 1 to M, resulting from the product between, on the one hand, a piece of data resulting from a i-order dyadic self-convolution of an element, corresponding to the given sequential component, of the transformed series and, on the other hand, the corresponding predistortion coefficient.

Thus, the predistortion model is based on a Volterra series reduced with a so-called MP model (standing for “Memory Polynomial” in English).

In some aspects, the method comprises determining the predistortion coefficients based on a minimization of an error signal representative of a discrepancy between, on the one hand, the input signal and, on the other hand, a signal representative of a modulation of the amplified radiofrequency signal.

In some aspects, the method comprises determining the predistortion coefficients based on a minimization of an error signal representative of a discrepancy between, on the one hand, the input signal and, on the other hand, a second output signal generated by application of said predistortion method to an input signal representative of a modulation of the amplified radiofrequency signal.

Thus, the coefficients of the predistortion model are determined directly.

In some aspects, the method comprises determining the predistortion coefficients based on a minimization of an error signal representative of a discrepancy between, on the one hand, a signal representative of a modulation of a second radiofrequency signal generated from said non-predistorted input signal and amplified by the power amplifier and, on the other hand, said output signal.

Thus, the coefficients of the model are firstly determined in order to model the power amplifier. Thus, the predistortion coefficients are determined from the coefficients modeling the power amplifier (for example, by inversion of a matrix comprising the coefficients modeling the power amplifier).

In some aspects, said determination implements, for said minimization, a technique belonging to the group comprising:
Least squares
Normalized least squares;
Gauss-Newton algorithm; or
Recursive least squares.

In some aspects, said technique is implemented in the Walsh domain based on the signals making up the transposed error signal in the Walsh domain.

Thus, the computational load is reduced for the determination of the predistortion coefficients.

In some aspects, said determination is performed periodically.

Thus, the variations of the characteristics of the power amplifier (for example, in temperatures or in aging) are taken into account in the model.

The disclosure also relates to a computer program comprising program code instructions for implementing a predistortion method as described before, according to any one of its different aspects, when it is executed on a computer.

In an aspect of the disclosure, a predistortion electronic device is provided comprising a reprogrammable computing machine or a dedicated computing machine configured to implement the steps of the predistortion method according to the disclosure (according to any one of the aforementioned different aspects). Thus, the features and advantages of this device are the same as those of the corresponding steps of the previously-described predistortion method. Consequently, they are not described in any further detail.

The disclosure also relates to a radiofrequency emitter comprising a predistortion electronic device as described before (according to any one of the aforementioned different aspects).

### BRIEF DESCRIPTION OF THE DRAWINGS

Other aims, features and advantages of the disclosure will appear more clearly upon reading the following description, given as a simple illustrative and non-limiting example, with reference to the figures, wherein:

FIG. 1, discussed hereinabove in the section “Prior art and its drawbacks”, shows a radiofrequency emitter implementing a digital predistortion block according to a known technique;

FIG. 1a, discussed above in the section “Prior art and its drawbacks”, illustrates the transfer function of the digital predistortion block of [FIG. 1];

FIG. 1b, discussed hereinabove in the section “Prior art and its drawbacks”, illustrates the transfer function of the PA of [FIG. 1];

FIG. 1c, discussed hereinabove in the section “Prior art and its drawbacks”, illustrates the overall transfer function corresponding to the composition of the transfer functions of the digital predistortion block and of the PA of [FIG. 1];

FIG. 2 illustrates a radiofrequency emitter implementing a digital predistortion block according to an aspect of the disclosure;

FIG. 3 shows the steps of a predistortion method according to an aspect of the disclosure;

FIG. 4 shows an example of a device structure enabling the implementation of some steps of the predistortion method of [FIG. 3] according to an aspect of the disclosure.

### DETAILED DESCRIPTION

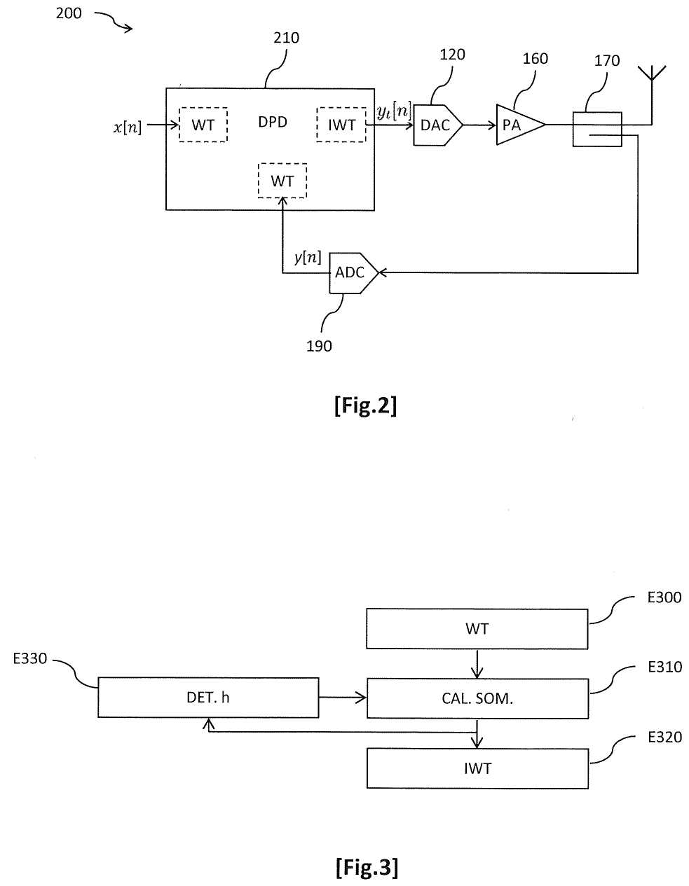

A radiofrequency emitter 200 implementing a digital predistortion block 210 according to an aspect of the disclosure is now described with reference to [FIG. 2].

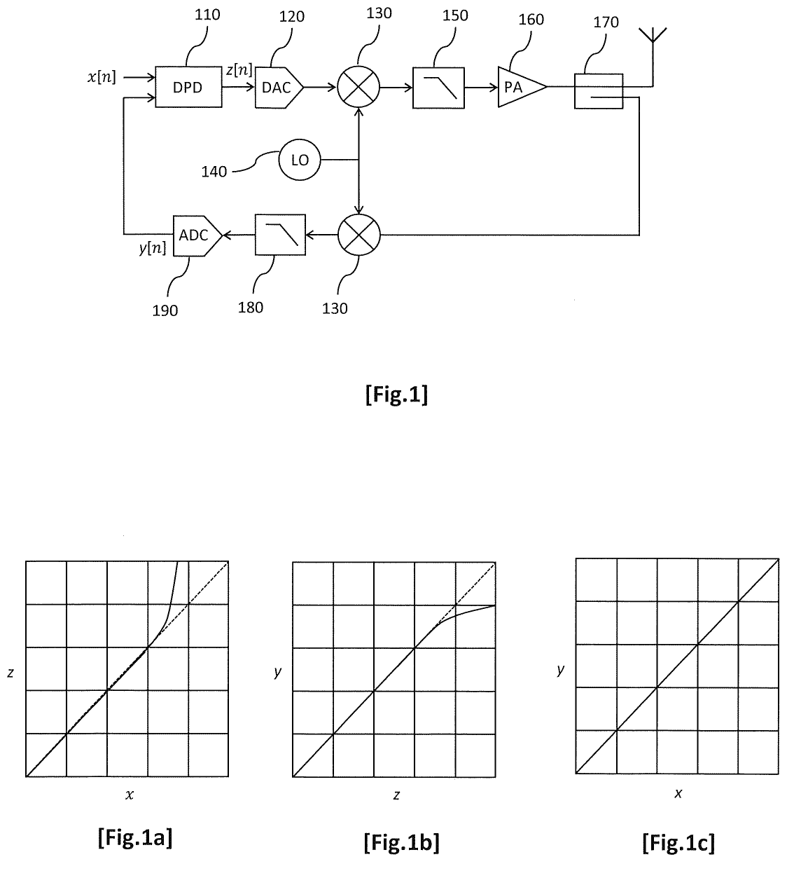

With regards to the known architecture described hereinabove with reference to [FIG. 1], the emitter 100 comprises a predistortion block 210 implementing the predistortion method described in more detail hereinbelow with reference to [FIG. 3]. Such a method is based on the implementation of a digital predistortion model based on the implementation of a Volterra series implemented in the Walsh domain. More particularly, the binary structure of the Walsh sequences and the structure of the digital calculations that result therefrom in the Walsh domain allow reducing the computational load in comparison with known techniques.

In particular, such an approach enables an implementation of the predistortion model in baseband as well as in intermediate frequency and even directly in radiofrequencies. This is why, according to the aspect of [FIG. 2], the predistortion block 210 directly processes the radiofrequency signal such that it should be amplified by the PA 160 before radiation by the antenna.

However, in other aspects, the predistortion block 210 processes a baseband or intermediate frequency input signal. In this case, the output signal delivered by the predistortion block 210 is for example transposed into radiofrequencies according to an architecture of the type like that of [FIG. 1], for example via a mixer 130 fed by a local oscillator 140. In this case, a mixer 130 also fed by the local oscillator 140 may be used on the feedback loop in order to generate the signal used by the predistortion block 210 in order to update its model.

In other aspects, we take advantage of the binary nature of the Walsh sequences in order to implement the inverse Walsh transform in a semi-analog manner. More particularly, each sequential component Y_{t,n} of the predistorted output signal [symbol] [n] is converted into analog via a 1-bit DAC (for example of the buffer type) amplitude-controlled by the reverse Walsh sequence corresponding to the considered sequential component. The different outputs of the 1-bit DACs are summed together in the analog domain in order to obtain the continuous-time version of the output signal [symbol] [n].

The steps of a predistortion method according to an aspect of the disclosure are now described with reference to [FIG. 3].

### 1. Step E300

During a step E300, a Walsh transform is applied to at least one series of M terms dependent on at least one series of M temporal samples x[n] of the input signal delivering M sequential components of at least one corresponding transformed series.

### 1.1 General Case

More particularly, the predistortion model considered herein is based on a Volterra series transposed into the Walsh domain. It should be noted that such a model applies to the modeling of the transfer function of the PA 160 as well as to the predistortion, as such, of the input signal x[n]. Only the coefficients involved in both cases change as described hereinbelow with reference to step E330. Returning back to step E300, the following formulation of a Volterra series is considered in the time domain:

$${y}_{t} [ n ] = {\sum }_{q = 1}^{Q} {y}_{i}^{( q )} [ n ] \qquad [ Math . 1 ]$$

where [symbol] [n] is the sample of index n at the output of the block 210, and where:

$$\begin{matrix}{y}_{t}^{( q )} [ n ] = {\sum }_{{m}_{1} = 0}^{M - 1} {\sum }_{{m}_{2} = 0}^{M - 1} … {\sum }_{{m}_{q} = 0}^{M - 1} {h}^{( q )} ( {m}_{1} , {m}_{2} , … {m}_{q} ) \\ x [ n - {m}_{1} ] x [ n - {m}_{2} ] … x [ n - {m}_{q} ]\end{matrix} \qquad [ Math . 2 ]$$

with:
   h^{(q)}(m₁, m₂, . . . , m_{q}) the Volterra kernels; and
   x[n−m₁]x[n−m₂] . . . x[n−m_{q}] the Volterra waveforms.

In order to be able to apply a discrete Walsh transform, the Volterra waveforms are segmented into series consisting of M waveforms, herein organized in the form of vectors.

Thus, the following vectors are obtained for the linear waveforms:

$${x}_{0 , n} = [ \begin{matrix}x [ nM ] \\ x [ nM - 1 ] \\ ⋮ \\ x [ nM - M + 1 ]\end{matrix} ] … {x}_{{m}_{1} , n} = [ \begin{matrix}x [ nM - {m}_{1} ] \\ x [ nM - 1 - {m}_{1} ] \\ ⋮ \\ x [ nM - M + 1 - {m}_{1} ]\end{matrix} ] \qquad [ Math . 3 ]$$

for the quadratic waveforms:

$${x}_{00 , n} = [ \begin{matrix}{x}^{2} [ nM ] \\ {x}^{2} [ nM - 1 ] \\ ⋮ \\ {x}^{2} [ nM - M + 1 ]\end{matrix} ] … {x}_{{m}_{1} {m}_{2} , n} = [ \text{} \begin{matrix}x [ nM - {m}_{1} ] x [ nM - {m}_{2} ] \\ x [ nM - 1 - {m}_{1} ] x [ nM - 1 - {m}_{2} ] \\ ⋮ \\ x [ nM - M + 1 - {m}_{1} ] x [ nM - M + 1 - {m}_{2} ]\end{matrix} ] \qquad [ Math . 4 ]$$

and generally for the q-order waveforms;

$$[ Math . 5 ]$$

$${x}_{{m}_{1} {m}_{2} ⋯ {m}_{q} , n} = [ \begin{matrix}x [ nM - {m}_{1} ] x [ nM - {m}_{2} ] ⋯ x [ nM - {m}_{q} ] \\ x [ nM - 1 - {m}_{1} ] x [ nM - 1 - {m}_{2} ] ⋯ x [ nM - 1 - {m}_{q} ] \\ ⋮ \\ x [ nM - M + 1 - {m}_{1} ] x [ nM - M + 1 - {m}_{2} ] ⋯ x [ nM - M + 1 - {m}_{q} ]\end{matrix} ]$$

Thus, by applying a discrete Walsh transform on the aforementioned series, we obtain the vectors:

$${X}_{{m}_{1} {m}_{2} ⋯ {m}_{q} , n} = {W}_{L} {x}_{{m}_{1} {m}_{2} ⋯ {m}_{q} , n} = [ \begin{matrix}{X}_{{m}_{1} {m}_{2} ⋯ {m}_{q} , n} [ 1 ] \\ {X}_{{m}_{1} {m}_{2} ⋯ {m}_{q} , n} [ 2 ] \\ ⋮ \\ {X}_{{m}_{1} {m}_{2} ⋯ {m}_{q , n}} [ M ]\end{matrix} ] \qquad [ Math . 6 ]$$

with W_{L} the M-order Walsh matrix (as defined for example in the article by J. Johnson and M. Puschel, “In search of the optimal walsh-hadamard transform,” in 2000 IEEE International Conference on Acoustics, Speech, and Signal Processing. Proceedings (Cat. No.00CH37100), vol. 6, 2000, pp. 3347-3350 vol.6).

By adopting an equivalent segmentation for the Volterra kernels, after carrying out a discrete Walsh transform of dimension M, we obtain the vectors:

$${H}_{{m}_{1} {m}_{2} ⋯ {m}_{q} , n} = {W}_{L} {h}_{{m}_{1} {m}_{2} ⋯ {m}_{q} , n} = [ \begin{matrix}{H}_{{m}_{1} {m}_{2} ⋯ {m}_{q , n}} [ 1 ] \\ {H}_{{m}_{1} {m}_{2} ⋯ {m}_{q , n}} [ 2 ] \\ ⋮ \\ {H}_{{m}_{1} {m}_{2} ⋯ {m}_{q , n}} [ M ]\end{matrix} ] \qquad [ Math . 7 ]$$

Thus, the Volterra series given by the equation [Math.1] is transposed into the Walsh domain, corresponding to a Walsh transform of dimension M, in the form:

$${Y}_{t , n} = {{\sum }_{q = 1}}^{Q} {{\sum }_{{m}_{1} = 0}}^{M - 1} {{\sum }_{{m}_{2} = 0}}^{M - 1} ⋯ {{\sum }_{{m}_{q} = 0}}^{M - 1} {X}_{{m}_{1} {m}_{2} ⋯ {m}_{q} , n} \cdot {H}_{{m}_{1} {m}_{2} ⋯ {m}_{q} , n} \qquad [ Math . 8 ]$$

with Y_{t,n} the value of the sequential component of index n, n an integer from 0 to M−1, in the Walsh domain, of the output signal [symbol] [n] of the block 210.

### 1.2 MP Case

In order to further reduce the computational load implemented in the predistortion block 210, a simplified model based on Volterra series is implemented in some aspects.

Among the models that are commonly used, there is the MP model (standing for “Memory Polynomial” in English). In this case, we have m₁=m₂= . . . =m_{q}=0 and the equation [Math.8] is reduced to:

$$\text{?} = {\sum }_{q = 1}^{Q} \text{?} {H}_{q , n} \qquad [ Math . 9 ]$$

$$with :$$

$${X}_{1 , n} = {W}_{L} {x}_{1 , n} … {X}_{Q , n} = {W}_{L} {x}_{Q , n} \qquad [ Math . 10 ]$$

$$where :$$

$${x}_{1 , n} = [ \begin{matrix}x [ nM ] \\ x [ nM - 1 ] \\ ⋮ \\ x \text{?} nM - M + 1 ]\end{matrix} ] … {x}_{Q , n} = [ \begin{matrix}{x}^{Q} [ nM ] \\ {x}^{Q} [ nM - 1 ] \\ ⋮ \\ {x}^{Q} [ nM - M + 1 ]\end{matrix} ] \qquad [ Math . 11 ]$$

$$\text{?} \text{indicates text missing or illegible when filed}$$

### 1.3 Multiplication Vs. Dyadic Convolution

Reconsidering the general expression [Math.5] or the simplified expression of the MP model [Math.11], it is observed that the Walsh transform of the Volterra waveforms of some orders involves the Walsh transform of one (or more) series in which one (or more) term(s) is/are dependent on:
the product between two temporal samples x[n] of the input signal; and/or
at least one temporal sample x[n] of the input signal raised to an integer power.

Yet, the Walsh transform of a product of operands is equal to the dyadic convolution of the Walsh transforms of said operands, as recalled, for example, in the article by M. Z. Anna Usakova, Jana Kotuliakova, “Journal of electrical engineering,” vol. 53, no. 9-10. Cambridge, LA: MIT Press, 1958, pp. 285-288. In other words:

$${X}_{m 1 m 2 , n} = {X}_{m 1 , n} {X}_{m 2 , n} \qquad [ Math . 12 ]$$

where [symbol] represents the dyadic convolution. Such an implementation is very effective with regards to the computational load. Indeed, the dyadic convolution of x and y is expressed as:

$$x = x y z [ n ] = \frac{1}{P} {\sum }_{p = 0}^{p} x ( p ) y ( n ⊕ p ) \qquad [ Math . 13 ]$$

with p⊕n the dyadic sum of p and n. Such a dyadic sum is expressed, when p and n are two positive integers such that:

$$p = {\sum }_{i = 0}^{∞} {p}_{i} {2}^{i} n = {\sum }_{i = 0}^{∞} {n}_{i} {2}^{i} \qquad [ Math . 14 ]$$

with pᵢ, nᵢ∈[0,1], as the expression:

$$p ⊕ n = {\sum }_{i = 0}^{∞} \vert {p}_{i} - {n}_{i} \vert {2}^{i} \qquad [ Math . 15 ]$$

Thus, depending on the considered aspects, the Walsh transform of the Volterra waveforms of some orders implements:
at least one dyadic convolution between two elements, corresponding to a given sequential component, corresponding to the Walsh transform of two series of temporal samples x[n] of the input signal; and/or
at least one dyadic self-convolution of an element, corresponding to a given sequential component, corresponding to the Walsh transform of a series of temporal samples x[n] of the input signal.

### 1.4 Conclusion In Step E300

According to the aspects described hereinabove with reference to step E300, in order to assess the Walsh transform of the Volterra waveforms, the following different configurations may be encountered:
a Walsh transform is applied to a plurality of series of M terms dependent on one or more corresponding series of M temporal samples x[n] of the input signal: this is for example the general case corresponding to the equation [Math.5] when all or part of the multiplications (or rises to power, which remain interpreted as multiplication calculations) are implemented in the time domain before carrying out the Walsh transform of the considered series, the other multiplications (or rises to power which remain interpreted as multiplication calculations) being implemented in the Walsh domain in the form of dyadic convolutions (or dyadic self-convolution, where appropriate) of elements of some transformed series;
a Walsh transform is applied to a plurality of series of M terms dependent on one single series of M temporal samples x[n] of the input signal: this is for example the case MP corresponding to the equation [Math.11] and when all or part of the rises to power (which remain interpreted as multiplication calculations) are implemented in the time domain before carrying out the Walsh transform of the considered series, the other rises to power being implemented in the Walsh domain in the form of dyadic self-convolutions of elements of some transformed series;
a Walsh transform is applied to one single series of M terms dependent on one single series of M temporal samples x[n] of the input signal: it is for example the case MP corresponding to the equation [Math.11] and when the rises to power (which remain interpreted as multiplication calculations) are implemented in the Walsh domain in the form of dyadic self-convolutions of elements of the transformed series, the order of the dyadic self-convolutions corresponding to the considered rise to power.

Irrespective of the considered aspect, the application of a Walsh transform to a given series of M terms dependent on at least one series of M temporal samples x[n] of the input signal delivers M sequential components of a corresponding transformed series.

### 2. Step E310

During a step E310, for at least one given sequential component of the Walsh domain, it is proceeded with a calculation of at least one sum of a plurality of operands resulting from the product between, on the one hand, a piece of data dependent on at least one element, corresponding to the given sequential component, of a transformed series X and, on the other hand, a corresponding predistortion coefficient H delivering a sequential component Y_{t,n} of a predistorted transformed input signal.

More particularly, referring to the equations [Math.8] and [Math.9], it appears that such summed operands result from weighting by a coefficient h, an element of the matrix H, of a piece of data dependent on:
one single element of a transformed series X: this is the case where the multiplications (or rises to power which remain interpreted as multiplication calculations) are implemented in the time domain before carrying out the Walsh transform of the considered series;
one (or more) dyadic convolution(s) between two elements, corresponding to the given sequential component, each belonging to a transformed series X: this is for example the general case corresponding to the equation [Math.5] when all or part of the multiplications are implemented in the time domain before carrying out the Walsh transform of the considered series, the other multiplications being implemented in the Walsh domain in the form of dyadic convolutions of elements of some transformed series; and/or
one (or more) dyadic self-convolution(s) of an element, corresponding to the given sequential component, of a transformed series X: this is for example the case MP corresponding to the equation [Math.11] and when all or part of the rises to power (which remain interpreted as multiplication calculations) are implemented in the Walsh domain in the form of dyadic self-convolutions. For example, in an optimized case with regards to the computational load associated with a model MP, said sum is a sum of M operands. The i-th operand, i being an integer from 1 to M, results from the product between, on the one hand, an i-order dyadic self-convolution of an element, corresponding to the given sequential component, of the transformed series X and, on the other hand, the corresponding predistortion coefficient. Thus, only dyadic self-convolutions are implemented, thereby reducing the computational load.

Returning back to step E310, said repeated calculation for the M sequential components of the Walsh domain delivering the M sequential components Y_{t,n}, n an integer from 0 to M−1, of the predistorted transformed input signal as indicated by the equations [Math.8] and [Math.9].

### 3. Step E320

During a step E320, an inverse Walsh transform is applied to the M sequential components Y_{t,n} of the predistorted transformed input signal delivering the output signal [symbol] [n] for the generation of the radiofrequency signal. In other words, the radiofrequency signal is generated from the output signal [symbol] [n], itself dependent on the input signal x[n].

As discussed hereinabove with reference to [FIG. 2], depending on the considered aspect, the predistortion block 210 processes an input signal which may be in baseband, in intermediate frequency or directly on the radiofrequency carrier of interest. In the latter case, the output signal [symbol] [n] generated in step E320 is directly the radiofrequency signal (aspect illustrated in [FIG. 2]). In the aspects wherein the input signal is in baseband or in intermediate frequency, the radiofrequency signal is generated from the output signal [symbol] [n] via a frequency transposition as discussed hereinabove.

Moreover, depending on the considered aspects, the inverse Walsh transform is implemented in a purely digital manner (aspect illustrated in [FIG. 2]), or it takes advantage of the binary nature of the Walsh sequences in order to implement the inverse Walsh transform in a semi-analog manner as discussed hereinabove with reference to [FIG. 2].

### 4. Step E330

The predistortion coefficients H implemented during step E310 are determined in order to compensate for the effect of the transfer function of the PA 160. For example, a calibration of the PA 160 is performed at production and one (or more, for example depending on the temperature or on aging of the component) set of predistortion coefficients H is thus determined.

Alternatively, the predistortion coefficients H are determined by the predistortion block 210 via the feedback loop illustrated in [FIG. 2]. For example, such a determination is performed upon initialization of the emitter 200, or periodically during the transmission in order to take account of the variation of the characteristics of the power amplifier during the transmission of the radiofrequency signal.

More particularly, three different variants are described hereinbelow for the determination of the predistortion coefficients H by the predistortion block 210.

### 4.1 Variant 1

In this first variant, depending on the architecture of the emitter 200 of [FIG. 2], the determination of the predistortion coefficients H is performed based on a minimization of an error signal representative of a discrepancy between:
the input signal x[n]; and
the signal y[n] representative of the modulation of the amplified radiofrequency signal.

In other words, it is herein sought to minimize the discrepancy between the modulation of the amplified radiofrequency signal, i.e. having undergone the distortion of the PA 160, and the input signal conveying the non-distorted modulation.

Depending on the aspects, such a minimization implements a technique belonging to the group comprising:
Least squares
Normalized least squares;
Gauss-Newton algorithm; or
Recursive least squares.

Advantageously, such a minimization technique is implemented in the Walsh domain based on the signals making up the error signal transposed into the Walsh domain. In the present case, the error signal in the Walsh domain is in the form:

$${E}_{n} = {X}_{n} - {Y}_{n} \qquad [ Math . 16 ]$$

For example, the application of a least squares algorithm as detailed in the work by N. Wiener, “Nonlinear Problems in Random Theory,” Cambridge, LA: MIT Press, 1958, leads to the following predistortion coefficients update equation:

$${H}_{n + 1} = {H}_{n} + 2 μ \text{?} {E}_{n} \text{?} {X}_{n} \qquad [ Math . 17 ]$$

$$\text{?} \text{indicates text missing or illegible when filed}$$

with μ the adaptation step and, in the case of a general Volterra series:

$${X}_{n} = [ \begin{matrix}{X}_{1 , n} & … & \text{?} & … & \text{?}\end{matrix} ] \qquad [ Math . 18 ]$$

$$and :$$

$${H}_{n} = [ \begin{matrix}{H}_{1 , n} & … & \text{?} & … & \text{?}\end{matrix} ] \qquad [ Math . 19 ]$$

$$\text{?} \text{indicates text missing or illegible when filed}$$

Each coefficient of H is updated once for each new data block X (for example fed at a predefined refresh rate). The estimation gradient is calculated as an average of the data instead of its instantaneous value like in the time domain approach. Consequently, it consists of a more accurate representation of the actual gradient and leads to a faster convergence of the algorithm. For N1 iterations, N1×M data points are necessary. For example, in the case of the MP model, each iteration requires Q+1 Walsh transforms (i.e. M×log2(M) additions and/or subtractions in the case of a so-called “fast” implementation of the Walsh transform), (Q×M) multiplications and/or additions for the adaptation of the model and (Q×M) multiplications and/or additions for the update of the coefficients. Thus, the computational complexity of the algorithm is O(2×N1×Q×M+(Q+1)×M×log2(M)).

### 4.2 Variant 2

In this second variant, the determination of the predistortion coefficients H is performed based on a minimization of an error signal representative of a discrepancy between:
the input signal x[n]; and
a second output signal generated by application of the present predistortion method to an input signal equal to the signal y[n] representative of the modulation of the amplified radiofrequency signal.

In other words, it is herein sought to directly obtain the compensation, by the predistortion block 210, of the distortion induced by the PA 160 by feeding at the input of the considered block 210 the signal y[n] representative of a modulation of the amplified radiofrequency signal and by comparing the output of the block 210 with the input signal x[n].

Depending on the aspects, such a minimization implements one of the techniques mentioned before in the context of the variant 1.

Advantageously, such a minimization technique is implemented in the Walsh domain based on the signals making up the error signal in the Walsh domain. In the present case, the error signal in the Walsh domain is in the form:

$${E}_{n} = {X}_{n} - \text{?} \qquad [ Math . 20 ]$$

$$\text{?} \text{indicates text missing or illegible when filed}$$

with X_{t,n} said second output signal, transposed into the Walsh domain, generated by application of the present predistortion method to an input signal equal to the signal y[n] representative of the modulation of the amplified radiofrequency signal. Thus, in the case of a general Volterra series:

$$\text{?} = {\sum }_{q = 1}^{Q} {\sum }_{{m}_{1} = 0}^{M - 1} {\sum }_{{m}_{2} = 0}^{M - 1} … {\sum }_{{m}_{q} = 0}^{M - 1} \text{?} \qquad [ Math . 21 ]$$

$$\text{?} \text{indicates text missing or illegible when filed}$$

For example, the application of a least squares algorithm as mentioned before in the context of the variant 1 leads to the following predistortion coefficients update equation:

$${H}_{n + 1} = {H}_{n} + 2 μ \text{?} {E}_{n} \text{?} {Y}_{n} \qquad [ Math . 22 ]$$

$$\text{?} \text{indicates text missing or illegible when filed}$$

The same advantages as those discussed in the context of the variant 1 are herein found when implementing the variant 2.

### 4.3 Variant 3

In this third variant, the determination of the predistortion coefficients H is performed based on a minimization of an error signal representative of a discrepancy between:
a signal representative of a modulation of a second radiofrequency signal generated from said non-predistorted input signal x[n] and amplified by the PA 160; and the output signal [symbol] [n].

In other words, it is herein sought to obtain, in a first step, coefficients H_{PA} allowing modeling the PA 160 by making the coefficients of the model converge so as to obtain, at the output of the block 210, an image signal of the second radiofrequency signal obtained at the output of the PA 160. Thus, in the present variant, the signal at the output of the model is, in the case of a general Volterra series, in the form:

$$\text{?} = {\sum }_{q = 1}^{Q} {\sum }_{{m}_{1} = 0}^{M - 1} {\sum }_{{m}_{2} = 0}^{M - 1} … {\sum }_{{m}_{q} = 0}^{M - 1} \text{?} \qquad [ Math . 23 ]$$

$$\text{?} \text{indicates text missing or illegible when filed}$$

The predistortion coefficients H are obtained from the coefficients modeling the power amplifier, for example according to the approach proposed in the article by Yu and E. Zhu, “A comparative study of learning architecture for digital predistortion”, 2015 Asia-Pacific Microwave Conference (APMC), 2015, pp. 1-3, via the equation:

$$H = \text{?} \qquad [ Math . 24 ]$$

$$\text{?} \text{indicates text missing or illegible when filed}$$

Depending on the aspects, the minimization of the error signal implements one of the techniques mentioned in the context of the variant 1.

Advantageously, such a minimization technique is implemented in the Walsh domain based on the signals making up the error signal in the Walsh domain. In the present case, the error signal in the Walsh domain is in the form:

$${E}_{n} = {Y}_{n}^{′} - \text{?} \qquad [ Math . 25 ]$$

$$\text{?} \text{indicates text missing or illegible when filed}$$

with Yₙ^{t} said signal representative of a modulation of a second radiofrequency signal generated from said non-predistorted input signal x[n] and amplified by PA 160.

For example, in the case of a general Volterra series, the application of a least squares algorithm as mentioned before in the context of the variant 1, leads to the following equation of update of the coefficients of the model implemented in the block 210:

$$\text{?} = \text{?} + 2 μ \text{?} {E}_{n} \text{?} {X}_{n} \qquad [ Math . 26 ]$$

$$\text{?} \text{indicates text missing or illegible when filed}$$

The same advantages as those discussed in the context of the variant 1 are found herein when implementing the variant 3.

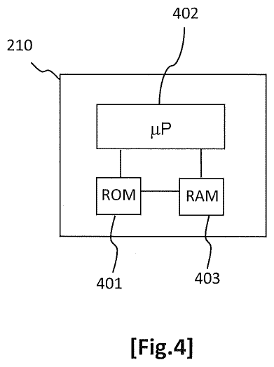

An example of a structure of the device 210 allowing implementing all or part of the steps of the predistortion method of [FIG. 3] according to an aspect of the disclosure is now described with reference to [FIG. 4].

The device 210 comprises different means such as a random-access memory 403 (for example a RAM memory), a processing unit 402 equipped for example with a processor, and controlled by a computer program stored in a read-only memory 401 (for example a ROM memory or a hard disk). On initialization, the code instructions of the computer program are for example loaded into the random-access memory 403 before being executed by the processor of the processing unit 402.

This [FIG. 4] illustrates only a particular manner, among several possible ones, for making the device 210 so that it performs all or some of the steps of the predistortion method of [FIG. 3] (according to any one of the aspects and/or variants described hereinabove with reference to [FIG. 3]). Indeed, these steps can be carried out indifferently on a reprogrammable computing machine (a PC computer, a DSP processor or a microcontroller) executing a program comprising a sequence of instructions, or on a dedicated computing machine (for example a set of logic gates like an FPGA or an ASIC, or any other hardware module).

In the case where the device 210 is made with a reprogrammable computing machine, the corresponding program (i.e. the sequence of instructions) could be stored in a storage medium, removable (such as for example a CD-ROM, a DVD-ROM, a USB key) or not, this storage medium could be read partially or entirely by a computer or a processor.

In some aspects, the device 210 also comprises means for implementing the inverse Walsh transform in a semi-analog manner as discussed hereinabove with reference to [FIG. 2]. For example, such means comprise:
a plurality of 1-bit DACs (for example of the buffer type), each DAC being amplitude-controlled by the inverse Walsh sequence corresponding to the sequential component considered for the inverse transformation; and
an analog summer in order to sum up the outputs of the different 1-bit DACs together and thus generate an analog quantity (voltage or current) representative of the inverse Walsh transform of the predistorted transformed input signal so as to generate the output signal.

Thus, in all aspects, the device 210 comprises means configured to execute all or part of the steps of the predistortion method of [FIG. 3] (according to any one of the aspects and/or variants described hereinabove with reference to [FIG. 3]).

In some aspects, the device 210 is implemented in the radiofrequency emitter 200.

What is claimed is:

1. A method for predistorting an input signal to compensate for the effect, on a radiofrequency signal generated from the input signal, of a non-linear transfer function of a power amplifier configured to amplify the radiofrequency signal,
characterized in that an electronic device performs:
carrying out a Walsh transform of at least one series of M terms dependent on at least one series of M temporal samples of the input signal delivering M sequential components of at least one corresponding transformed series;
for at least one given sequential component of the Walsh domain, calculating at least one sum of a plurality of operands resulting from the product between, on the one hand, a piece of data dependent on at least one element, corresponding to the given sequential component, of a transformed series and, on the other hand, a corresponding predistortion coefficient delivering a sequential component of a predistorted transformed input signal, at least one piece of data being dependent on at least one dyadic convolution between two elements, corresponding to the given sequential component, each belonging to a transformed series and/or being dependent on at least one dyadic self-convolution of an element, corresponding to the given sequential component, of a transformed series, the sum following a structure of a Volterra series, dependent on temporal samples of the input signal, transposed into the Walsh domain,
the predistortion coefficients being determined in order to compensate for the effect of the transfer function of the power amplifier, said repeated calculation for the M sequential components of the Walsh domain delivering M sequential components of the predistorted transformed input signal; and
carrying out an inverse Walsh transform of the M sequential components of the predistorted transformed input signal delivering an output signal for the generation of the radiofrequency signal.

2. The method according to claim 1, wherein said Walsh transform is applied to a plurality of series of M terms dependent on at least one series of M temporal samples of the input signal delivering M sequential components of a plurality of corresponding transformed series, and wherein said at least one piece of data depends on:
at least one dyadic convolution between two elements, corresponding to the given sequential component, each belonging to a transformed series of the plurality of transformed series; and/or
at least one dyadic self-convolution of an element, corresponding to the given sequential component, of a transformed series of the plurality of transformed series,
and wherein the sum follows a structure of a Volterra series, dependent on said plurality of series of M temporal samples of the input signal, transposed into the Walsh domain.

3. The method according to claim 2, wherein at least one series of M terms comprises at least one term dependent on:
the product between two temporal samples of the input signal; and/or
at least one temporal sample of the input signal raised to an integer power.

4. The method according to claim 1, wherein said Walsh transform is applied to a plurality of series of M terms dependent on a series of M temporal samples of the input signal delivering M sequential components of a plurality of corresponding transformed series,
and wherein said at least one piece of data depends on at least one dyadic self-convolution of an element, corresponding to the given sequential component, of a transformed series of the plurality of transformed series.

5. The method according to claim 4, wherein at least one series of M terms comprises at least one term dependent on at least one temporal sample of the input signal raised to an integer power.

6. The method according to claim 1, wherein said Walsh transform is applied to a series of M terms corresponding to a given series of M temporal samples of the input signal delivering M sequential components of a corresponding transformed series,
and wherein said calculation comprises calculating a sum of M operands, the i-th operand, i an integer from 1 to M, resulting from the product between, on the one hand, a piece of data resulting from a i-order dyadic self-convolution of an element, corresponding to the given sequential component, of the transformed series and, on the other hand, the corresponding predistortion coefficient.

7. The method according to claim 1, comprising determining the predistortion coefficients based on a minimization of an error signal representative of a discrepancy between, on the one hand, said input signal and, on the other hand, a signal representative of a modulation of said amplified radiofrequency signal.

8. The method according to claim 1, comprising determining the predistortion coefficients based on a minimization of an error signal representative of a discrepancy between, on the one hand, said input signal and, on the other hand, a second output signal generated by application of said method to an input signal representative of a modulation of said amplified radiofrequency signal.

9. The method according to claim 1, comprising determining the predistortion coefficients based on a minimization of an error signal representative of a discrepancy between, on the one hand, a signal representative of a modulation of a second radiofrequency signal generated from said non-predistorted input signal and amplified by the power amplifier and, on the other hand, said output signal.

10. The method according to claim 7, wherein said determination implements, for said minimization, a technique belonging to the group comprising:
Least squares;
Normalized least squares;
Gauss-Newton algorithm; or
Recursive least squares.

11. The method according to claim 10, wherein said technique is implemented in the Walsh domain based on the signals making up the transposed error signal in the Walsh domain.

12. The method according to claim 7, wherein said determination is performed periodically.

13. A computer program product comprising program code instructions for implementing the method according to claim 1, when said program is executed on a computer.

14. An electronic device for predistorting an input signal to compensate for the effect, on a radiofrequency signal generated from the input signal, of a non-linear transfer function of a power amplifier configured to amplify the radiofrequency signal, characterized in that it comprises means configured to implement a predistortion method according to claim 1.

15. A radiofrequency emitter comprising a device according to claim 14.
